(19) United States
(12) Patent Application Publication
(10) Pub. No.: US 2013/0062599 A1
(43) Pub. Date: Mar. 14, 2013

(54) ORGANIC LIGHT EMITTING DEVICES HAVING GRADED EMISSION REGIONS

(71) Applicants: Russell J. Holmes, Chanhassen, MN (US); Nicholas Erickson, St. Paul, MN (US)

(72) Inventors: Russell J. Holmes, Chanhassen, MN (US); Nicholas Erickson, St. Paul, MN (US)

(21) Appl. No.: 13/701,208

(22) PCT Filed: Jun. 1, 2011
(86) PCT No.: PCT/US11/38792

§ 371 Date: Nov. 30, 2012

Related U.S. Application Data
(60) Provisional application No. 61/350,315, filed on Jun. 1, 2010.

(51) Int. Cl. H01L 51/52; H01L 51/56

(52) U.S. Cl. 257/40; 438/37; 257/E51.022; 257/E51.001

(57) ABSTRACT

Organic light-emitting devices having an emissive region comprising a hole transport material and an electron transport material in varying material concentration across the devices. Variation of the concentration of the hole transport material and electron transport material is provided continuously or in a graded manner, as opposed to using multiple layers arranged to form a step-like gradient.

### CROSS-REFERENCE TO RELATED APPLICATION

The present application claims priority to U.S. Provisional Application No. 61/350,315, filed Jun. 1, 2010, the entire disclosure of which is incorporated herein by reference for all purposes.

### TECHNICAL FIELD

The present invention relates to organic light emitting devices. More particularly, aspects of the present invention relate to organic light-emitting devices having an emissive region comprising a hole transport material and an electron transport material in varying material concentration across the devices.

### BACKGROUND

Organic light emitting devices (OLEDs) have drawn interest for use in applications such as displays and lighting due to their potential for high efficiency and compatibility with high-throughput manufacturing. The design of an efficient phosphorescent OLED typically may require, however, highly specialized active materials and intricate device architectures.

High efficiency phosphorescent OLEDs typically include either a double emissive layer or a mixed-host emissive layer containing a fluorescent host material and one or more guest materials (phosphorescent or fluorescent). A schematic view of an exemplary OLED is shown in FIG. 1. Typical OLEDs also include one or more blocking layers that function to confine injected charge carriers and mobile excitons to the emissive layer, enhancing the rate of exciton formation and ultimately, the external quantum efficiency (EQE).

A double-emissive (D-EML) layer architecture contains hole and electron transport layers forming an emissive region that has both hole and electron-transporting characteristics. With a phosphorescent emitter doped throughout the emissive region, the recombination zone is effectively spread between the separate hole and electron transporting layers, widening the region where excitons may form and improving the utilization of charge in those regions.

In contrast, a mixed-host (MH) emissive layer architecture includes an emissive region which contains both electron-transporting and hole-transporting material (ETM and HTM, respectively) in a single layer, as well as a phosphorescent emitter. This emissive region contains a large amount of interfacial area between the ETM and HTM, thus creating favorable conditions for exciton formation. In these multi-layered architectures additional charge-injection, charge-transport, and charge blocking layers are crucial in determining the overall charge balance and device performance. Simplifying these structures entails eliminating some or all of the additional charge injection, transport, and blocking layers.

In most conventional OLED architectures, electron-hole charge balance is optimized through the careful inclusion of charge blocking layers and charge carrier injection layers in order to prevent charge carrier leakage from the emissive layer/region and reduce charge injection barriers at the electrodes. While effective in realizing exceptionally high quantum and power efficiencies, these additional layers can complicate device processing and cost, and may also complicate the engineering of device architectures for long lifetime.

### SUMMARY

Aspects of the present invention thus provide OLEDs having efficient charge balance, high efficiency, and less complex device architectures. In particular, single layer architectures having an emissive region comprising an HTM and an ETM in varying material concentration across the device are provided. For example, the emissive region can include 100% HTM at the anode to 100% ETM at the cathode, in which the concentrations of the HTM and ETM vary over the emissive region from the anode to the cathode. Preferably such variation of the concentration of the HTM and/or ETM in a mixed emissive region is provided continuously or in a graded manner, as opposed to using multiple layers arranged to form a step-like gradient (with sharp interfaces between the different layers). With a continuous concentration variation, the barriers for charge injection and charge transport throughout the device can be reduced thus allowing simpler device architectures.

In certain exemplary devices in accordance with the present invention, charge balance in a single-layer device entails balancing the injection barrier of the anode to the highest-occupied molecular orbital (HOMO) of the HTM and the injection barrier of the cathode to the lowest-unoccupied molecular orbital (LUMO) of the ETM. Additionally, obtaining charge balance may entail selecting the HTM and ETM to have similar mobilities such that charges reach the middle of the emissive layer at equal rates.

Single layer devices in accordance with the present invention can mitigate these strict constraints: as the concentration of HTM changes to ETM, holes injected into the HTM encounter fewer molecules favorable to conduction; similarly, as the concentration of ETM changes to HTM, electrons injected into the ETM encounter fewer molecules favorable to conduction. This unique property creates symmetric transport conditions for electrons and holes, improving and, in some cases, maximizing charge balance.

### BRIEF DESCRIPTION OF THE DRAWINGS

The accompanying drawings, which are incorporated in and constitute a part of this disclosure, illustrate several aspects of the present invention and together with description of the exemplary embodiments serve to explain the principles of the present invention. A brief description of the drawings is as follows:

FIG. 1 schematically shows an exemplary planar organic light-emitting device.

FIG. 2 schematically shows an exemplary OLED in accordance with an aspect of the present invention having a continuously varying/graded-emissive layer with varying concentrations of HTM and ETM.

FIG. 3(a) shows composition in wt. % of an exemplary graded-emissive layer device in accordance with an aspect of the present invention from anode (0 nm) to cathode (100 nm). Ir(ppy)3 doped at 2 wt. % throughout.

FIG. 3(b) shows an energy diagram depicting highest-occupied molecular orbitals (HOMOs) and lowest-unoccupied molecular orbitals (LUMOs) of exemplary materials that can be used to form OLEDS in accordance with an aspect of the present invention. Dashed lines indicate dopant.

FIG. 4(a) shows normalized electroluminescence spectra of a MH device, a D-EML device and an exemplary continuously varying/graded-emissive layer device in accordance with an aspect of the present invention, taken at 1000 cd/m2.

FIG. 4(b) shows electroluminescence spectra of an exemplary continuously varying/graded-emissive layer device in accordance with an aspect of the present invention for increasing current density.

FIG. 5(a) shows current density versus voltage (J-V) characteristics for a MH device (square), a D-EML device (circle), and an exemplary continuously varying/graded-emissive layer (triangle) device in accordance with an aspect of the present invention.

FIG. 5(b) shows brightness versus voltage (B-V) characteristics for a MH device (square), a D-EML device (circle), and an exemplary continuously varying/graded-emissive layer device in accordance with an aspect of the present invention (triangle). Turn-on voltage for the MH device is 5.0 V, for both D-EML and graded-emissive layer devices turn-on voltage is 2.55 V.

FIG. 6(a) shows external quantum efficiencies (EQE) for a MH device (square), a D-EML device (circle), and an exemplary continuously varying/graded-emissive layer device in accordance with an aspect of the present invention (triangle). Continuously varying/graded-emissive layer devices in accordance with an aspect of the present invention show large (˜40%) enhancement over comparable D-EML device.

FIG. 6(b) shows power efficiencies (PE) for a MH device (square), a D-EML device (circle), and an exemplary continuously varying/graded-emissive layer device in accordance with an aspect of the present invention (triangle). Continuously varying/graded-emissive layer devices in accordance with an aspect of the present invention show large (˜40%) enhancement over comparable D-EML device.

FIG. 7(a) shows the composition gradient in wt. % for 2:1 overall ratio composition gradient with zero-endpoints for an exemplary continuously varying/graded-emissive layer device in accordance with an aspect of the present invention.

FIG. 7(b) shows the composition gradient in wt. % for 1:1 overall ratio composition gradient with zero-endpoints for an exemplary continuously varying/graded-emissive layer device in accordance with an aspect of the present invention.

FIG. 7(c) shows the composition gradient in wt. % for 1:2 overall ratio composition gradient with zero-endpoints for an exemplary continuously varying/graded-emissive layer device in accordance with an aspect of the present invention.

FIG. 8(a) shows external quantum efficiencies (EQE) for exemplary 2:1, 1:1, and 1:2 zero-endpoint continuously varying/graded-emissive layer OLEDs with Ir(ppy)3 in accordance with an aspect of the present invention.

FIG. 8(b) shows external quantum efficiencies (EQE) for exemplary 2:1, 1:1, and 1:2 zero-endpoint continuously varying/graded-emissive layer OLEDs with PQIr in accordance with an aspect of the present invention.

FIG. 9(a) shows the hole and electron mobilities at an applied field of 0.37 MV/cm for exemplary continuously varying/graded-emissive layer OLEDs in accordance with an aspect of the present invention containing TCTA as an HTM, BPhen as an ETM, and Ir(ppy)3 as an emitter.

FIG. 9(b) shows the hole and electron mobilities at an applied field of 0.44 MV/cm for exemplary continuously varying/graded-emissive layer OLEDs in accordance with an aspect of the present invention containing TCTA as an HTM, BPhen as an ETM, and PQIr as an emitter.

FIG. 10 shows external quantum efficiencies (EQE) for exemplary 2:1, 1:1, and 1:2 zero-endpoint continuously varying/graded-emissive layer OLEDs with FIrpic in accordance with an aspect of the present invention.

FIG. 11 shows the hole and electron mobilities at an applied field of 0.3 MV/cm for exemplary continuously varying/graded-emissive layer OLEDs in accordance with an aspect of the present invention containing TCTA as an HTM, TPBi as an ETM, and FIrpic as an emitter.

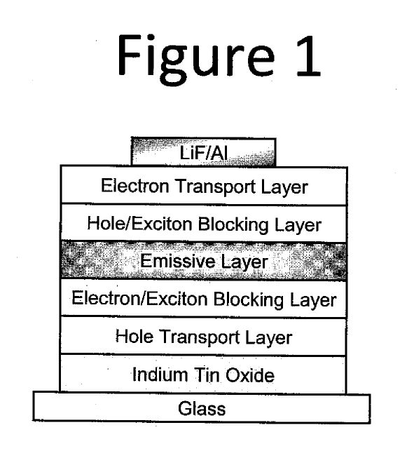

### DETAILED DESCRIPTION

The exemplary embodiments of the present invention described herein are not intended to be exhaustive or to limit the present invention to the precise forms disclosed in the following detailed description. Rather the exemplary embodiments described herein are chosen and described so those of ordinary skill in the art can appreciate and understand the principles and practices of the present invention. Additionally, the accompanying drawings, which are incorporated in and constitute a part of this disclosure, illustrate several aspects of the present invention and together with the description of the exemplary embodiments serve to explain the principles of the invention.

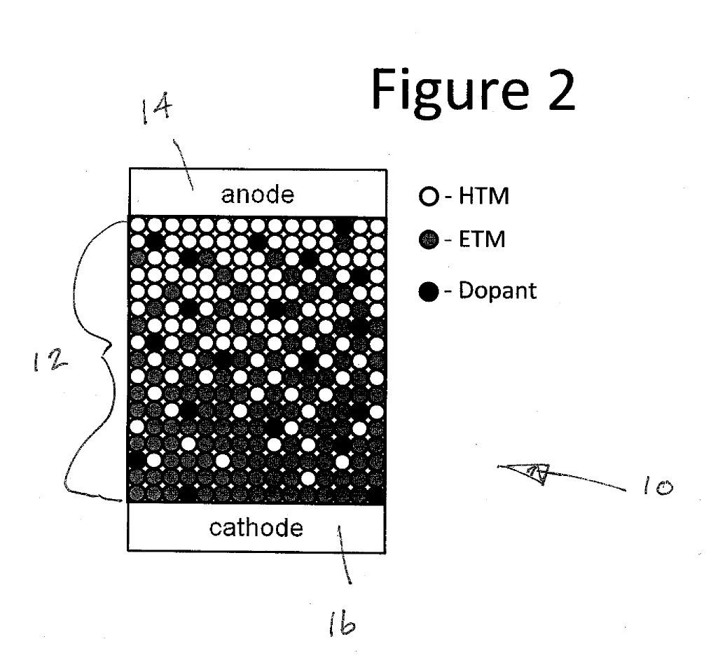

An exemplary OLED 10 in accordance with an aspect of the present invention having an emission region 12 with varying concentrations of HTM and ETM is schematically shown in FIG. 2. As shown, exemplary OLED 10 includes anode 14 and cathode 16. Anode 14 and/or cathode 16 can be formed on or in contact with an optional substrate (not shown). The light emission region 12 of OLED 10 preferably comprises a hole transport-electron transport heterojunction including a predetermined mixture of a HTM and ETM.

In the light emission region 12, the concentration of each of the HTM and ETM vary across a predetermined portion of light emission region 12 such as from a first side of the light emission region 12 to a second opposite side of the light emission region 12 in a predetermined continuous manner. For purposes of the present disclosure, continuous means that the variation or gradient of HTM and ETM preferably occurs smoothly without interruption across a predetermined portion of light emission region 12 rather than in a stepwise or discontinuous manner. As used herein, graded emission layer/region (G-EML) and gradient profile refer to such continuous variation of HTM and ETM within a desired portion light emission region 12. The HTM and ETM can vary in concentration in any desired manner and any ratio(s). The same rate of change need not be used across the entire device. The HTM and ETM can include organic semiconductor material. For example, the HTM can include 4,4′,4″-tris(carbazol-9-yl)triphenylamine (TCTA) whereas the ETM can include 4,7-diphenyl-1,10-phenanthroline (Bphen). Other organic semiconductor material can be used for the HTM and ETM, as well and as are conventionally known.

To provide light emission at a selected wavelength during operation of the device, the light emission region 12 can be doped with a guest organic material. The type of guest material(s) is preferably selected based on the desired light emission wavelength. For example, the guest material can include the phosphorescent guest, fac-tris(2-phenylpyridine) iridium (III) (Ir(ppy)3 which emits in the green region of the visible spectrum. To provide for light emission over other regions of the electromagnetic spectrum, the light emission region 12 may be doped with other additional guest organic material. For example, the light emission region 12 may be doped with two, three, four, or more different types of organic guest material, in which each different guest material is configured to emit light from a different region of the electromagnetic spectrum.

Multiple light emissive regions 12 may be stacked on one another, in which each light emission region in the stack preferably includes a dopant guest material that is configured to emit light at a different wavelength. For example, a white light emitting organic device (WOLED) utilizing a varying concentration light emission region in accordance with the present invention may include a single region containing one or more dopant guest materials for emitting light. The guest emitting material may be fluorescent or phosphorescent.

Alternatively, a WOLED may be formed of several light emission regions, each of which can use a varying concentration emission regions in accordance with the present invention. In addition, each of the light emission regions may contain no light emitting dopant guest materials or one or more dopant guest materials configured to emit light at different wavelengths. The multiple light emitting regions can be fabricated directly on top of each other in a stacked architecture. Alternatively, the light emitting regions can be fabricated side-by-side to achieve an aggregate broadband emission.

Stacked OLEDs typically contain two or more “sub-units” which are separated by internal contacts which may be connected to an external circuit (in a “parallel” configuration), or may serve as internal charge generating contacts (commonly referred to as Charge Generation Layers or CGL—in a “series” configuration). Devices which have CGLs contain two electrodes, such as in a typical OLED. The OLED sub-units usually contain multiple organic layers which serve functions similar to conventional OLED architectures, i.e. charge transport, charge confinement (to prevent leakage current), and exciton formation/light emission. These functions may be incorporated into a single region, through the use of the varying concentration region architecture in accordance with an aspect of the present invention, potentially reducing processing complexity and cost.

One or more varying concentration light emitting regions in accordance with the present invention can be included in an OLED, in which the one or more light emitting regions are each configured to form excimers or dimers under excitation, leading to broadband emission from the OLED. Although not required, the excimer or dimer emission may be achieved with the use of a dopant guest material.

In the light emission region 12, injected charge carriers are initially transported by the respective transport materials towards the center of the device. Due to the HOMO level alignment between the dopant guest organic material and the HTM, the guest organic material may act as a charge trap and excitons may form directly on the guest molecules. Direct excitation of the guest molecule avoids the need to rely on host-guest energy transfer to achieve light emission from the guest molecule, allowing for the use of low guest doping concentrations and thus achieving high ηPL efficiency. Additionally, direct excitation of the guest molecule allows for low-voltage device operation, giving high ηP. Furthermore, a large concentration of HTM near the anode and ETM near the cathode can, in some implementations, advantageously prevent charge carriers from leaking across the device, so they are confined to the central region of the emission region 12. Additionally, the lack of sharp interfaces and broad mixing of HTM and ETM in the host device may widen the recombination zone in which excitons recombine.

A light emitting device in which the concentration of the HTM (or ETM) is zero at an interface between the light emission region 12 and an adjacent region (i.e., the concentration of the HTM (or ETM) is 100% at the first interface) is designated has having a “zero endpoint.” A light emitting device in which the concentrations of both the HTM and ETM are non-zero at an interface between the light emission region 12 and an adjacent region is designated as having a “non-zero endpoint.” That is, one or more of the molecular layers in the light emission region 12 near an interface of the light emission region 12 and an adjacent region includes at least some hole transport material and some electron transport material. The interface may correspond to an interface between the light emission region 12 and any adjacent region contacting the light emission region 12, such as, for example, an anode or cathode. The light emitting device can have a zero or non-zero endpoint at both interfaces if desired.

The concentration profile of the HTM and/or ETM can vary over the thickness of the light emission region 12. For example, the concentration of the HTM and/or ETM may follow a linear increase or decrease over the thickness of the light emission region 12. Other composition profiles may be used as well. For example, in some implementations, the concentration of the HTM and/or ETM follows a quadratic, or exponential concentration profile. Alternatively, the composition profile of the light emission region 12 may follow a combination of linear, quadratic and exponential profiles.

### Examples

Organic light emitting devices were fabricated on glass substrates coated with a layer of indium-tin-oxide (ITO) with a sheet resistance of 15Ω/□. Substrates were degreased with detergent and solvents and subsequently treated in UV-ozone ambient prior to thin film deposition. Organic material was grown in the device using vacuum thermal sublimation (<10-7 Torr) without breaking vacuum. Graded emission region/layer (G-EML) green-light emitting OLEDs were fabricated using TCTA as the HTM, and Bphen as the ETM. These materials are well matched for optimum charge balance as both are characterized by charge carrier mobilities of about 10-4 cm2 V−1 s−1, as determined by the time-of-flight (TOF) method. The concentration of a green phosphorescent guest, factris(2-phenylpyridine) iridium (III) (Ir(ppy)3) was kept fixed throughout the emissive layer/region. Optimum performance is realized for an emissive layer/region that is 100-nm-thick containing 2 wt. % Ir(ppy)3.

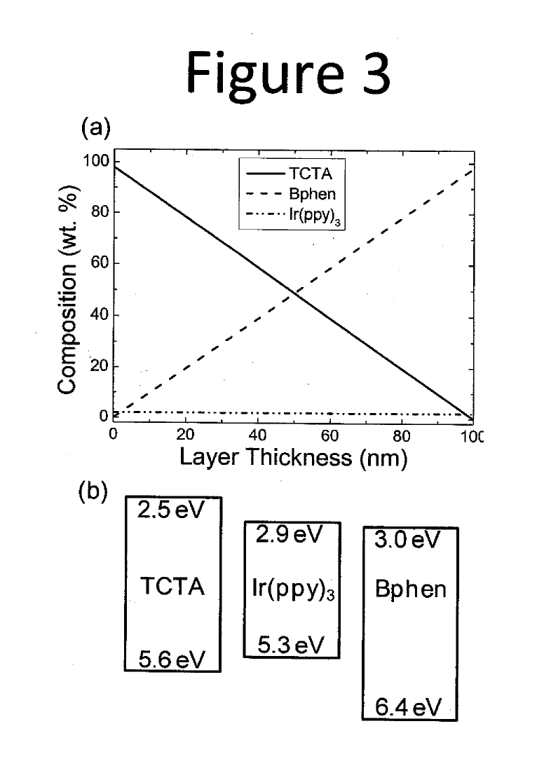

Experimentally, this structure was realized by co-depositing all three organic materials using the following rates (R): RTCTA=0.392 nm/s to 0 nm/s, RBphen=0 nm/s to 0.392 nm/s, and RIr(ppy)3=0.008 nm/s over 250 seconds. The time-varying deposition rates were controlled remotely and monitored in situ using three quartz crystal monitors. A cathode consisting of a 1-nm thick layer of LiF and a 75 nm thick layer of Al was subsequently deposited through a shadow mask to define devices with a diameter of 1 mm. The spatial composition of the device is shown in FIG. 3(a). The energy levels for the exemplary active materials of interest are shown in FIG. 3(b). In addition to the single layer/region, G-EML architecture, two OLEDs fabricated for comparison namely, a two-layer, double emissive layer (D-EML) device and a single-layer, mixed-emissive layer (M-EML) device. The layer structures for these devices are: 40 nm TCTA:Ir(ppy)3 (5 wt. %)/40 nm Bphen:Ir(ppy)3 (5 wt. %) for the D-EML OLED, and 80 nm TCTA:Bphen:Ir(ppy)3 (1:1:5 wt. %) for the M-EML OLED.

In some cases, low doping concentration in phosphorescent OLEDs can be advantageous, as the photoluminescence efficiency (ηPL) can approach unity at very low concentration (<1 mol. %). However, at doping concentrations of less than or equal to about 2 wt. %, OLED devices may exhibit poor efficiency. In addition, at such low concentrations, light emission from the host may be seen. This effect can be attributed to poor energy transfer from host to guest or, poor charge trapping and exciton formation directly on the guest. At very low concentration it is unlikely that Ir(ppy)3 participates in charge injection from the electrodes or contributes significantly to charge transport. In the G-EML, injected charge carriers are initially transported by the respective transport materials towards the center of the device.

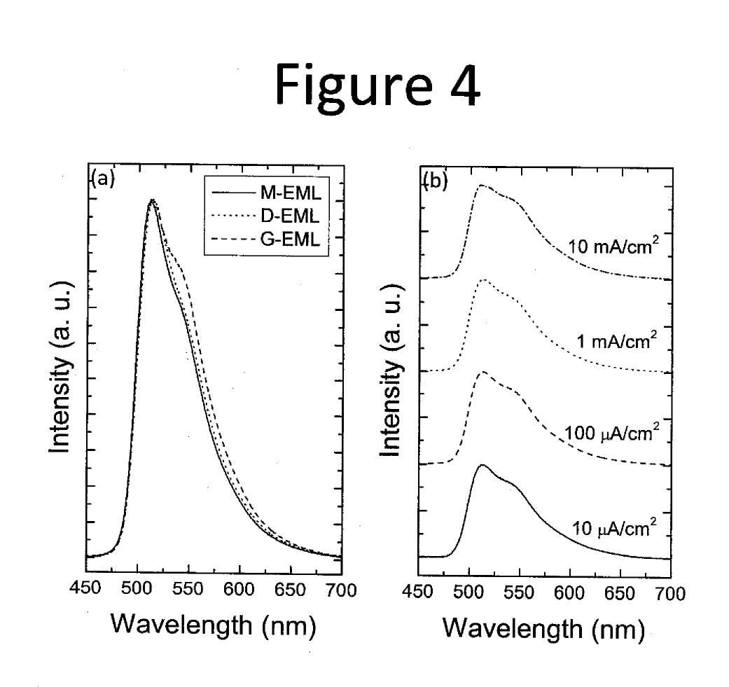

Due to the HOMO level alignment between Ir(ppy)3 and TCTA, Ir(ppy)3 may act as a charge trap and excitons may form directly on Ir(ppy)3. Direct excitation of the Ir(ppy)3 molecule avoids the need to rely on host-guest energy transfer to achieve Ir(ppy)3 emission, allowing for the use of low doping concentrations and thus achieving high ηPL efficiency. FIG. 4(a) shows the electroluminescent (EL) spectra of the example D-EML, M-EML, and G-EML devices. The characteristic Ir(ppy)3 emission is observed in each device, with no emission from either host material. As can be seen in FIG. 4(b), in the G-EML device, increasing current density shows little effect on the emission spectra, even for high brightness (>10,000 cd/m2 at 10 mA/cm2). The lack of host emission is further support for the direct charge-trapping model of Ir(ppy)3 excitation.

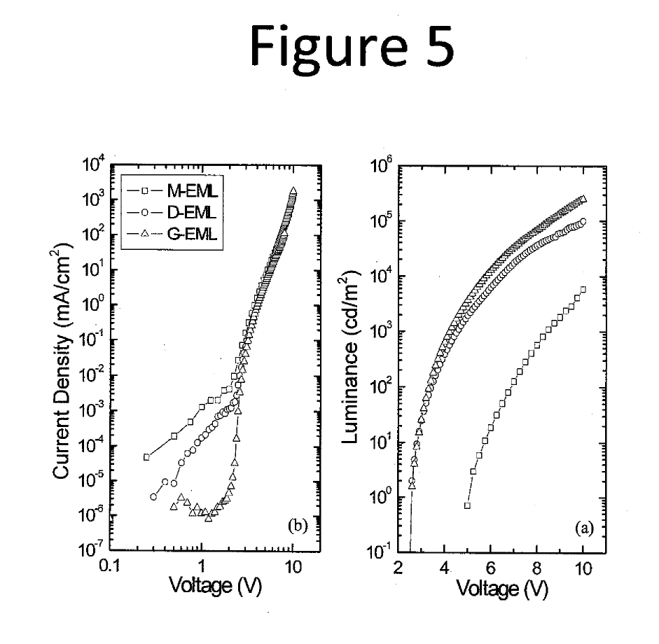

FIG. 5(a) shows the current density-voltage characteristics of the exemplary devices. Devices containing an M-EML exhibit the largest leakage current at low applied voltage. Since the M-EML devices have HTM and ETM dispersed throughout the device, continuous conduction pathways for both holes and electrons likely exist, permitting leakage currents to flow through the EML at low applied voltage. In the devices containing a D-EML, the separate layers of TCTA:Ir(ppy)3 and Bphen:Ir(ppy)3 present large energetic barriers for the leakage of electrons and holes, respectively. This effectively confines the charges carriers to the interface between the two EML layers. In the G-EML device, a large concentration of TCTA near the anode and Bphen near the cathode prevent charge carriers from leaking across the device, likely confining them to the central region of the G-EML. Additionally, the lack of sharp interfaces and broad mixing of HTM and ETM in the graded-host device may widen the recombination zone.

FIG. 5(b) shows the luminance-voltage characteristics of the simplified M-EML, D-EML, and G-EML devices. The device containing an M-EML requires the largest voltage of the example devices to realize measurable electroluminescence. The combination of low brightness and high leakage current is an indication that the M-EML device suffers from poor charge balance. This is primarily due to having ETM and HTM dispersed evenly across the device, as there is little barrier to prevent charge carriers from transporting from electrode to electrode. The D-EML and G-EML architectures reach peak luminance levels of about 120,000 cd/m2 and about 300,000 cd/m2 at a voltage of 10 V, respectively. These devices show high luminance at low voltage, with turn-on voltages (defined as the voltage for a luminance of 1 cd/m2) of 2.55 V. Exciton formation on either TCTA or Bphen would require an input energy equal or greater to the optical gap of the hosts, 3.3 eV and 3.4 eV respectively. These values, as determined by the onset of optical absorption, are much less than the threshold required for observable emission. Additionally, the energetic barrier for electron injection into TCTA and hole injection into Bphen is large while it is energetically favorable for holes to reside on Ir(ppy)3. This is additional evidence for direct exciton formation on Ir(ppy)3. The G-EML device shows further enhancement in brightness at high voltage, indicating that charge balance is improved over the D-EML device.

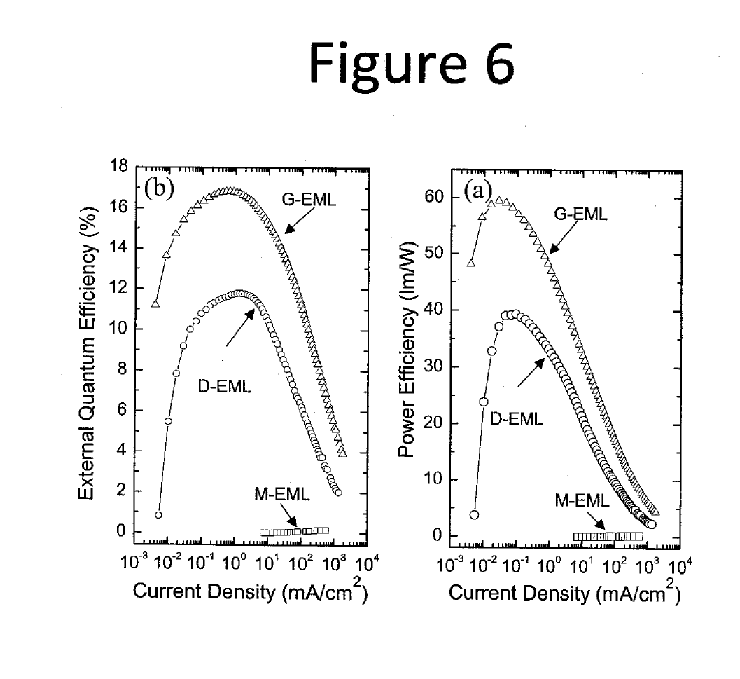

External quantum efficiency (EQE) versus current density and power efficiency (ηP) versus current density for the exemplary devices are shown in FIGS. 6(a) and 6(b). It is apparent that the poor charge balance in the M-EML device has an effect on its overall performance, only reaching EQE=((0.22±0.03) % and ηP=((0.25±0.03) lm/W. Improved charge confinement in the D-EML enhances charge balance over the M-EML device, allowing peak efficiencies of EQE=(11.8±0.4) % and ηP=(39.4±2.6) lm/W. Owing to the self-balancing nature of the continuously varying/graded-emissive region device, charge balance is nearly maximized. This leads to high quantum efficiency of (16.9±0.4) % and a high power efficiency of (61.0±1) lm/W.

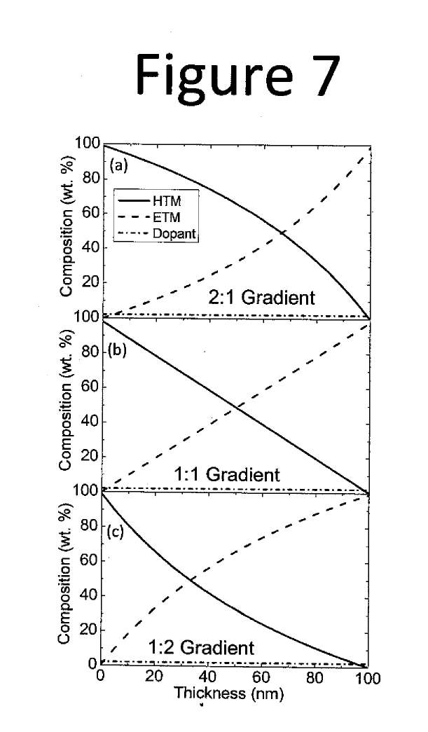

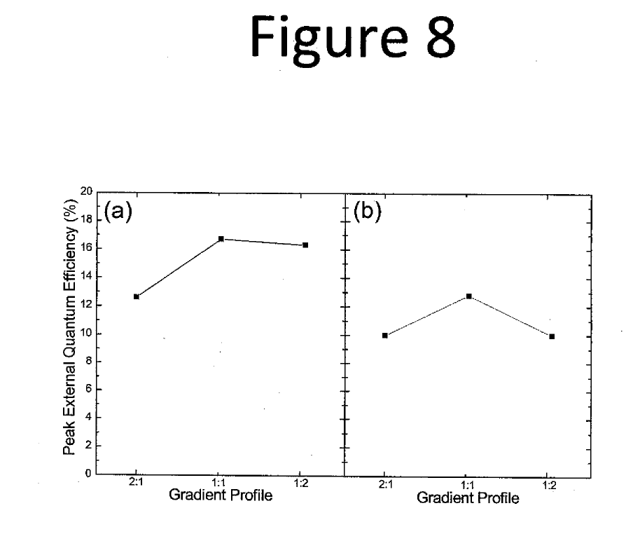

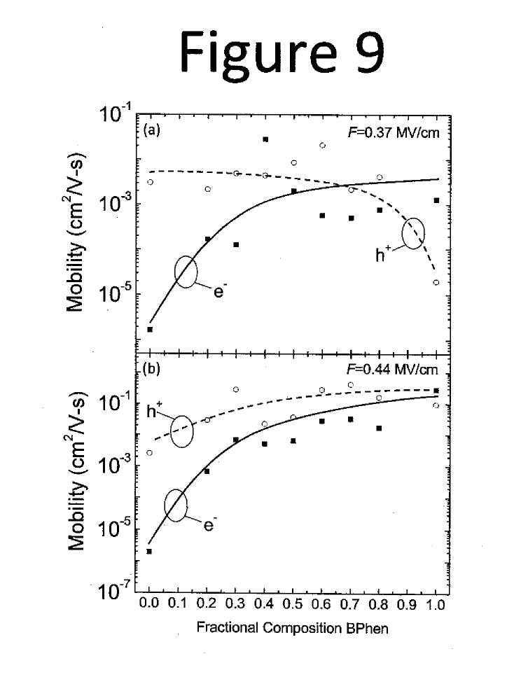

In a similar manner as above, red phosphorescent graded-emissive layer OLEDs were fabricated. In these devices, TCTA was chosen as an HTM, BPhen as an ETM, and the red phosphorescent emitter bis(1-phenylisoquinoline)-(acetylacetonate) iridium (III) (PQIr) was used as a dilutely-doped luminescent guest. Devices having differing gradient profiles, with differing overall ratios of HTM:ETM were fabricated, the profiles are shown in FIGS. 7(a) for a 2:1 profile, 7(b) for a 1:1 profile, and 7(c) for a 1:2 profile. The EQE of green Ir(ppy)3 and red PQIr devices having the overall compositions of 2:1, 1:1, and 1:2 are shown in FIGS. 8(a) and (b), respectively. It is evident that gradient profile and overall composition play a role in determining device efficiency. Through the use of single carrier device experiments, the electrical properties of the continuously varying/graded emissive layer devices were determined. The resulting electron and hole mobilities are shown at an applied field of 0.37 MV/cm and 0.44 MV/cm versus ETM composition for both devices containing Ir(ppy)3 and PQIr in FIGS. 9(a) and (b), respectively.

It is evident that across a wide range of TCTA:BPhen composition ratios the electron and hole mobilities are well-matched in magnitude. Additionally, the mobilities show little dependence on host composition, in the range of 80:20 to 20:80 TCTA:BPhen. At extreme ratios of host composition, containing ratios>80% of either host, the mobilities of both electrons and holes decrease by >2 orders of magnitude. The high charge balance achieved in the green and red 1:1 G-EML devices is likely the result of a few characteristics.

Efficient charge injection from the electrodes is maintained by the high composition of each transport material near its respective electrode. Charge carrier mobilities are high and well matched at moderate fields and remain so throughout the center region of the device. The mobility matching over a large range of compositions, and thus spatial extent, likely leads to increased overlap between electron and hole currents in the device allowing for efficient and broad exciton formation. As electrons (holes) approach the anode (cathode), the mobility decreases significantly, aiding charge confinement and reducing losses by leakage charge. Additionally, as charges are injected onto, and transported across, their respective transport material, there exists a large energy barrier to injection onto the opposing transport material. As there is a large amount of opposing transport material at the opposing electrode, this energy barrier also confines charges to the center region of the device. Ultimately, the confluence of these properties give high charge balance, with a 1:1 continuous variation/gradient offering the most symmetric injection and transport conditions and thus highest EQE.

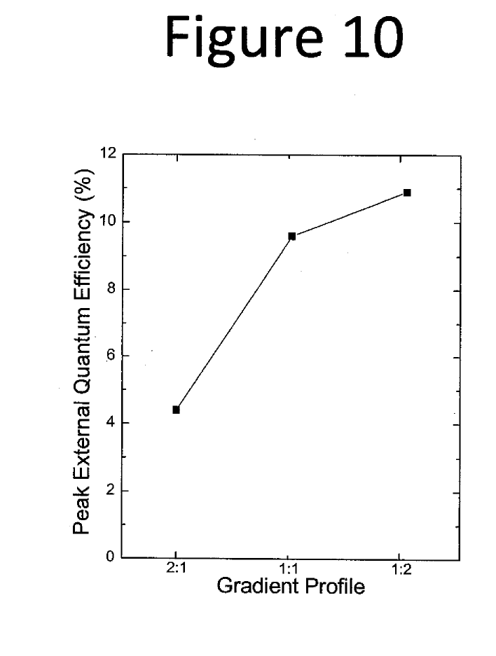

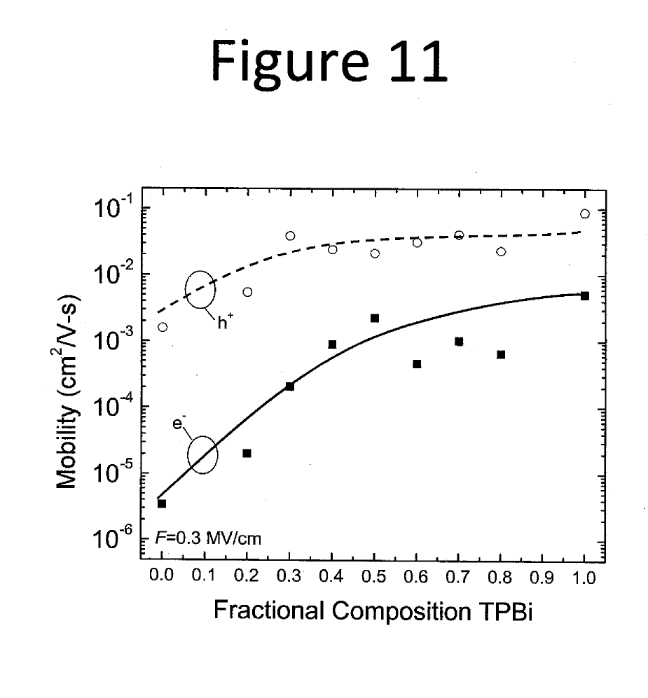

Additionally, single-layer blue light emitting continuously varying/graded-emissive layer OLEDs were fabricated using TCTA as an HTM, 2,2′,2″-(1,3,5-benzinetriyl)-tris(1-phenyl-1-H-benzimidazole) (TPBI) as an ETM, and iridium(III) bis[(4,6-difluorophenyl)-pyridinato-N,C2′]picolinate (FIrpic) as a blue phosphorescent emitter. The EQE of blue OLEDs having an overall continuous variation/gradient profile of 2:1, 1:1, and 1:2 are shown in FIG. 10. The electrical properties of this material system were studied by single-carrier devices, with the resulting hole and mobilities shown as function of ETM composition in FIG. 11.

In contrast to the TCTA:BPhen material system, the TCTA:TPBI material system shows charge carrier mobilities which are mismatched over a wide range of host compositions. It is observed that the electron mobility of TPBI shows a greater dependence on host composition than that of TCTA. It is also observed that TPBI doped with 7 wt. % FIrpic transports holes relatively well, with a hole mobility similar to that of TCTA doped with 7 wt. % FIrpic. Electron and hole currents in the 2:1 and 1:1 gradient profile OLEDs are likely mismatched, given the low mobility of electrons relative to holes in TCTA-rich compositions. The mismatch likely forces the exciton recombination zone towards the LiF/AI cathode side of the device, possibly exposing excitons to additional metal-quenching losses.

An electron-hole current mismatch may also cause holes to build up in the device due to the large energy barrier for hole injection onto TPBI. The sufficient accumulation of charge may eventually lower the barrier for injection of holes onto TPBI, at which point they are free to travel to the cathode, resulting in a reduction in charge balance via leakage current. In a 1:2 gradient device, however, there is a large spatial region of TPBI-rich host compositions. As the electron mobility is dependent on host composition, the 1:2 gradient profile device offers a larger spatial extent of relatively high electron mobility transport. The electron current is thus extended further into the device, moving the recombination zone away from the metal cathode towards the center of the device. Exciton formation and utilization will thus be improved in the 1:2 gradient device, which is observed as an improvement in charge balance and by extension, next.

Green, red, and blue OLEDs have been demonstrated which consist of a single, engineered organic layer. The devices exhibit high next and ηP owing to the high charge balance, low-voltage, and tunability of the G-EML device structure. Single-carrier devices have been used as a tool to extract the field-dependent mobility of a range of HTM:ETM composition ratios. The electron and hole mobilities of these compositions directly correspond to compositions found in the gradient profiles of the G-EML OLEDs and give information about the local electronic transport properties. The dependence of the electron and hole mobilities on compositions is found to be of importance in determining the optimal gradient profile for obtaining high charge balance. Material systems which have mismatched mobilities and varying degrees of dependence on HTM:ETM composition ratios are found to have differing optimal gradient profiles. The G-EML device structure is able to overcome the relative incompatibility in HTM and ETM mobilities through careful tuning of the gradient profile.

The present invention has now been described with reference to several exemplary embodiments thereof. The entire disclosure of any patent or patent application identified herein is hereby incorporated by reference herein for all purposes. The foregoing disclosure has been provided for clarity of understanding by those of ordinary skill in the art. No unnecessary limitations should be taken from the foregoing disclosure. It will be apparent to those of ordinary skill in the art that changes can be made in the exemplary embodiments described herein without departing from the scope of the present invention. Thus, the scope of the present invention should not be limited to the exemplary structures and methods described herein, but only by the structures and methods described by the language of the claims and the equivalents of those claimed structures and methods.

What is claimed is:

1. A light emitting device comprising a first light emission layer, the first light emission layer comprising a first hole transport material and a first electron transport material, wherein a concentration of at least one of the first hole transport material and the first electron transport organic material is graded continuously from a first side of the first light emission layer to a second side of the first light emission layer.

2. The light emitting device of claim 1 wherein the concentration of at least one of the first hole transport material and the first electron transport material is zero at the first side of the first light emission layer.

3. The light emitting device of claim 1 wherein the concentration of the first hole transport material is zero at the first side of the first light emission layer and the concentration of the first electron transport material is zero at the second side of the first light emission layer.

4. The light emitting device of claim 1 wherein the concentration of both the first hole transport material and the first electron transport material are graded continuously from the first side of the first light emission layer to the second side of the first light emission layer.

5. The light emitting device of claim 1 wherein the first hole transport material includes a first organic material and the electron transport material includes a second different organic material.

6. The light emitting device of claim 1 further comprising a first guest organic material, wherein the first guest organic material is configured to emit light of a first wavelength during operation of the light emitting device.

7. The light emitting device of claim 6 further comprising a second guest organic material, wherein the second guest organic material is configured to emit light of a second wavelength different from the first wavelength during operation of the light emitting device.

8. The light emitting device of claim 1, further comprising a second light emission layer on the first light emission layer.

9. A method of fabricating a light emitting device comprising: depositing a first hole transport material and a first electron transport material on a substrate to provide a first light emission layer, wherein a concentration of at least one of the first hole transport material and the first electron transport material is graded continuously from a first side of the first light emission layer to a second side of the first light emission layer.

10. The method of claim 9 wherein depositing the first hole transport material and the first electron transport material comprises depositing a non-zero concentration of at least one of the first hole transport material and the first electron transport material at the first side or the second side of the first light emission layer.

11. The method of claim 9 further comprising depositing a second donor type organic material and a second acceptor type organic material on the first light emission layer to provide a second light emission layer.

12. The method of claim 9 further comprising annealing the light emitting device.
